(19) United States
(12) Patent Application Publication
(10) Pub. No.: US 2011/0167321 A1
(43) Pub. Date: Jul. 7, 2011

(54) APPARATUS AND METHOD OF TRANSMITTING AND RECEIVING DATA FOR IMPROVING TRANSMISSION RATE

(75) Inventors: Sung-Hyun Hwang, Daejeon (KR); Jung Sun Um, Gyeonggi-do (KR); Myung Sun Song, Daejeon (KR); Chang-Joo Kim, Daejeon (KR); Se-Bin Im, Gyeonggi-do (KR); Tae-Woong Yoon, Jeju-do (KR); Hyung-Jin Choi, Seoul (KR)

(73) Assignees: Electronics and Telecommunications Research Institute, Daejeon (KR); Sungkyunkwan University Foundation for Corporate Collaboration, Gyeonggi-do (KR)

(21) Appl. No.: 12/809,392

(22) PCT Filed: Feb. 29, 2008
(86) PCT No.: PCT/KR08/01197

§ 371 Date: Jun. 18, 2010

(30) Foreign Application Priority Data
Dec. 18, 2007 (KR) 10-2007-0133811

(51) Int. Cl. H04L 27/28; H04B 17/00; H03M 13/23; G06F 11/10

(52) U.S. Cl. 714/786; 375/295; 375/224; 375/260; 714/E11.032

(57) ABSTRACT

A data transmitter and receiver for improving a data rate, and more particularly, to an apparatus and method of transmitting and receiving an orthogonal frequency division multiplexing (OFDM) symbol in which a pilot signal is added to a data signal is provided. The apparatus includes a transmitter including: a pilot adder to add a pilot signal to a data signal; and a guard interval inserting unit to insert a guard interval to the data signal with the added pilot signal, and a receiver including: a guard interval removal unit to remove a guard interval in a received time domain signal; a fast Fourier transform (FFT) unit to transform the time domain signal in which the guard interval is removed to a frequency domain signal; a channel estimator to estimate a channel value from the time domain signal in which the guard interval is removed; an equalizer to equalize the frequency domain signal based on the estimated channel value; and a pilot signal removal unit to remove the pilot signal in the equalized frequency domain signal.

### RELATED APPLICATIONS

This application is a 35 U.S.C. §371 national stage filing of PCT Application No. PCT/KR2008/001197 filed on Feb. 29, 2008, which claims priority to, and the benefit of, Korean Patent Application No. 10-2007-0133811 filed on Dec. 18, 2007. The contents of the aforementioned applications are hereby incorporated by reference.

### TECHNICAL FIELD

The present invention relates to a data transmitter and receiver for improving a data rate, and more particularly, to an apparatus and method of transmitting and receiving an orthogonal frequency division multiplexing (OFDM) symbol in which a pilot signal is added to a data signal.

This work was supported by the IT R&D program of MIC/IITA. [2005-S-002-03, CR (Cognitive Radio) Standardization Research]

### BACKGROUND ART

Generally, an orthogonal frequency division multiplexing (OFDM) scheme is being widely used in terrestrial digital broadcasting, a wireless local area network, and the like. The OFDM scheme may transmit data using a plurality of carriers. The OFDM scheme may be a type of a multi-carrier modulation (MCM) scheme that can convert symbol streams that are input in series, into parallel to thereby modulate the symbol streams into a plurality of subcarriers having orthogonality, that is, a plurality of subcarrier channels and to transmit the modulated symbol streams.

Since the OFDM scheme may transmit data using the plurality of subcarriers with maintaining the orthogonality between the plurality of subcarriers, it is possible to obtain the excellent data rate when transmitting high-speed data. Also, since a frequency spectrum is overlappingly used, frequency usage may be effective. The OFDM scheme may be robust with respect to frequency-selective fading and multi-path fading. Also, it is possible to reduce interference between symbols using a guard interval.

However, the OFDM scheme may allocate a pilot signal to a portion of carriers for the purpose of synchronization, channel estimation, and the like and thereby transmit signals. Therefore, a number of data subcarriers may be reduced in the entire used subcarriers, which results in relatively reducing a data rate.

According to a conventional art, there is some constraint on improving a data rate. Hereinafter, a transmitting method according to the conventional art will be described with reference to FIGS. 1 and 2.

FIG. 1 is a block diagram illustrating a structure of a transmitter and a receiver according to the conventional art.

FIG. 2 illustrates a signal structure of a transmitted symbol in an aspect of a frequency according to the conventional art.

Referring to FIGS. 1 and 2, the transmitter includes a subcarrier allocation unit 10, an inverse fast Fourier transform (IFFT) unit 20, and a guard interval inserting unit 30.

The subcarrier allocation unit 10 may receive a modulated data signal X_{d}[k] and a pilot signal Xₚ[k] and determine a transmission location of each signal in used subcarriers.

The pilot signal may be allocated to a pilot subcarrier. The pilot subcarrier may be disposed at a predetermined interval in the used subcarrier in order to estimate a frequency-selective fading channel in a multi-path channel environment. The IFFT unit 20 may transform an output signal X[k] of the subcarrier allocation unit 10 to a time domain signal X[n].

The guard interval inserting unit 30 may insert a guard interval to the time domain signal. The time domain signal with the inserted guard interval may be transmitted via a transmitting antenna.

The receiver may receive the time domain signal output from the transmitter.

The receiver includes a guard interval removal unit 40, an FFT unit 50, a subcarrier extractor 60, a channel estimator 70, and an equalizer 80.

The guard interval removal unit 40 may remove the guard interval in the received time domain signal.

The FFT unit 50 may transform an output signal Y[n] of the guard interval removal unit 40 to a frequency domain signal Y[k].

The subcarrier extractor 60 may separate a data symbol Y_{d}[k] and a pilot symbol Yₚ[k] from the frequency domain signal Y[k] of the FFT unit 50.

The channel estimator 70 may receives the pilot symbol to estimate a channel value Ĥ[k] of a frequency domain.

The equalizer 80 may compensate for a channel distortion based on the estimated channel value to output a compensated signal \hat{X}_{d}[k].

As described above, the transmitting method according to the conventional art may perform simple channel estimation using the pilot subcarrier. However, since the pilot subcarrier is used, the number of data subcarriers may be relatively reduced, deteriorating the entire transmission rate. Also, when the power of pilot subcarriers increases, interference with respect to an adjacent data signal may also increase.

### DISCLOSURE OF INVENTION

### Technical Goals

An aspect of the present invention provides a data transmitter and receiver for improving a data rate that can transmit a signal in which a pilot signal is added to a data signal allocated to a used subcarrier, instead of using a pilot subcarrier.

The present invention is not limited to the above purposes and other purposes not described herein will be apparent to those of skill in the art from the following description.

### Technical Solutions

According to an aspect of the present invention, there is provided a data transmitter for improving a data rate, the transmitter including: a pilot adder to add a pilot signal to a data signal; and a guard interval inserting unit to insert a guard interval to the data signal with the added pilot signal.

According to another aspect of the present invention, there is a data receiver for improving a data rate, the receiver including: a guard interval removal unit to remove a guard interval in a received time domain signal; a fast Fourier transform (FFT) unit to transform the time domain signal in which the guard interval is removed to a frequency domain signal; a channel estimator to estimate a channel value from the time domain signal in which the guard interval is removed; an equalizer to equalize the frequency domain signal based on the estimated channel value; and a pilot signal removal unit to remove the pilot signal in the equalized frequency domain signal.

According to still another aspect of the present invention, there is provided a data transmission method for improving a data rate, the method including: allocating a data signal to a subscriber; adding a pilot signal to the allocated data signal; and inserting a guard interval to the data signal with the added pilot signal to thereby transmit the data signal.

According to yet another aspect of the present invention, there is provided a data receiving method for improving a data rate, the method including: removing a guard interval in a received time domain signal; estimating a channel value from the time domain signal in which the guard interval is removed; compensating for the time domain signal in which the guard interval is removed with a channel distortion component based on the estimated channel value; and removing the pilot signal in the compensated signal to thereby extract the data signal.

### BRIEF DESCRIPTION OF DRAWINGS

FIG. 1 is a block diagram illustrating a structure of a transmitter and a receiver according to a conventional art;

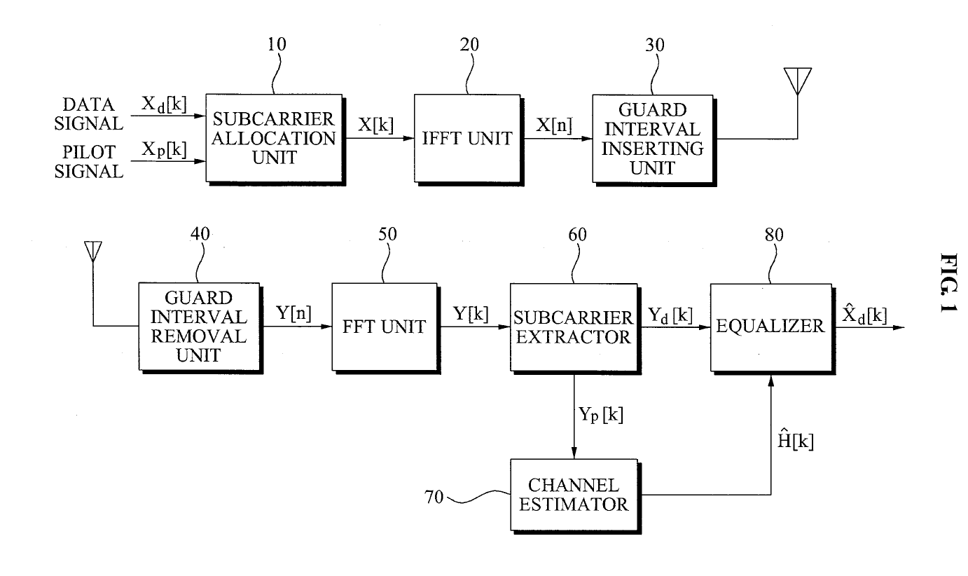

FIG. 2 illustrates a signal structure of a transmitted symbol in an aspect of a frequency according to the conventional art;

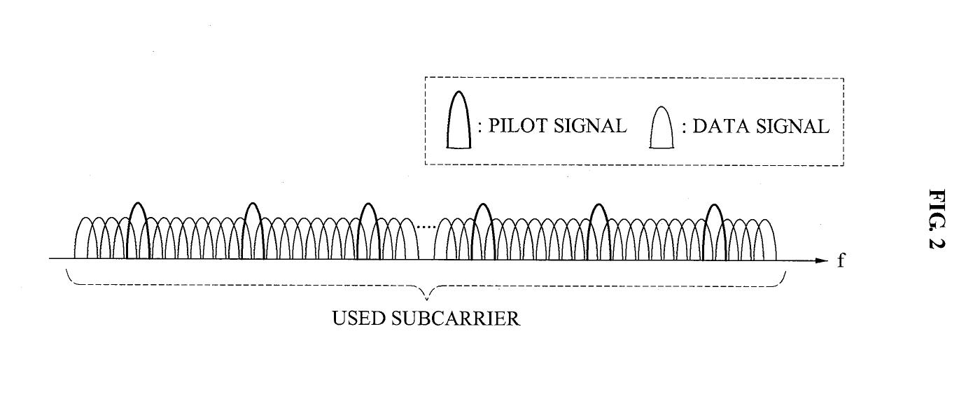

FIG. 3 is a block diagram illustrating a structure of a data transmitter and receiver for improving a data rate according to an embodiment of the present invention;

FIG. 4 illustrates a signal structure of a data signal with an added pilot signal, as a symbol transmitted and received by a transmitter and a receiver in an aspect of a frequency according to an embodiment of the present invention;

FIG. 5 is a flowchart illustrating a data transmitting and receiving method for improving a data rate according to an embodiment of the present invention; and

FIG. 6 illustrates a graph of comparing a data rate of the conventional data transmission method and a data rate of a data transmission method according to an embodiment of the present invention.

### BEST MODE FOR CARRYING OUT THE INVENTION

Reference will now be made in detail to embodiments of the present invention, examples of which are illustrated in the accompanying drawings, wherein like reference numerals refer to the like elements throughout. The embodiments are described below in order to explain the present invention by referring to the figures.

In the present invention, a pilot signal corresponding to a promised standard between a transmitter and a receiver may be basically used. In this instance, the pilot signal may be added to a data signal to thereby transmit the data signal instead of allocating a pilot subcarrier of the pilot signal. Therefore, it is possible to improve a data rate by using all the used subcarriers as a subcarrier of the data signal.

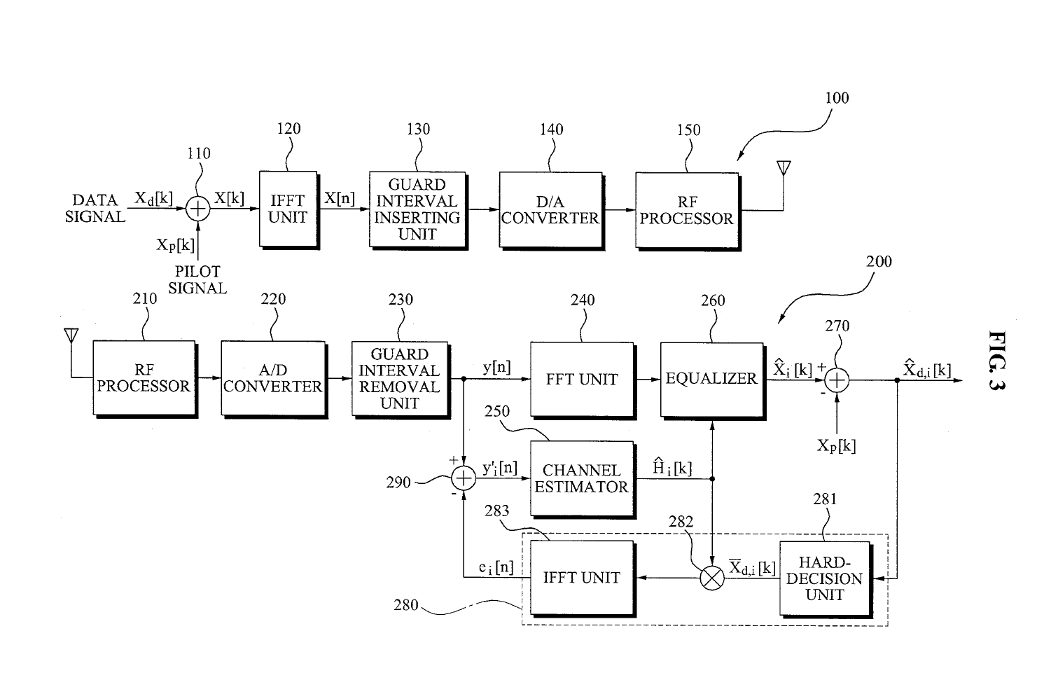

FIG. 3 is a block diagram illustrating a structure of a data transmitter and receiver for improving a data rate according to an embodiment of the present invention.

Referring to FIG. 3, a transmitter 100 includes an adder 110, an inverse fast Fourier transform (IFFT) unit 120, a guard interval inserting unit 130, a digital-to-analog (D/A) converter 140, and a radio frequency (RF) processor 150.

The adder 110 may add a pilot signal Xₚ[k] to a data signal X_{d}[k] of a frequency domain. The data signal X_{d}[k] is an input bit stream to be transmitted and may be an encoded data signal by an encoder (not shown). Also, the data signal may be a signal allocated to a used subcarrier by a subcarrier allocation unit (not shown). An output signal of the adder 110, that is, a signal X[k] in which the pilot signal Xₚ [k] is added to the data signal X_{d}[k] may be represented as,

X[k]=X_{d}[k]+Xₚ[k], (kεS_{used}: used subcarrier set). [Equation 1]

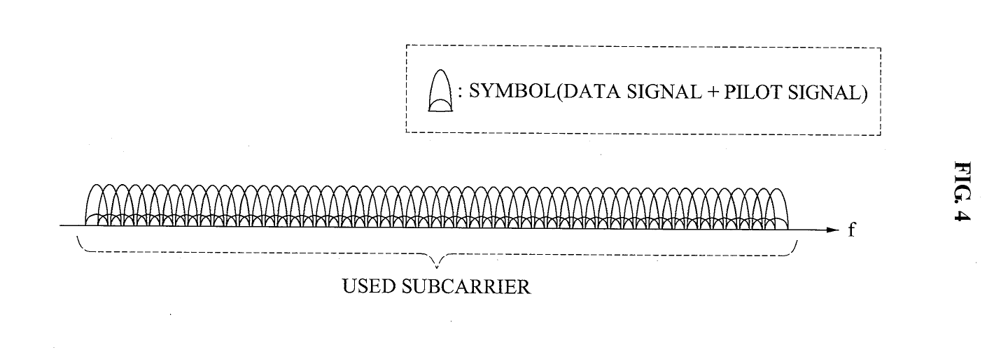

FIG. 4 illustrates a signal structure of a data signal with an added pilot signal, as a symbol transmitted and received by a transmitter and a receiver in an aspect of a frequency according to an embodiment of the present invention.

Referring to FIG. 4, the symbol includes a pilot signal and a data signal. Specifically, the pilot signal may be added to the data signal that is allocated to a subcarrier. The pilot signal may be used for synchronization, channel estimation, and the like. The power of the pilot signal may be set to be less than the power of the data signal to not cause interference with respect to an adjacent data signal.

The above signal structure may improve a data rate in comparison to a signal structure where the pilot signal is allocated to a pilot subcarrier. This is because all the used subcarriers may be used as the subcarrier of the data signal as the data signal is added to the pilot signal instead of using the pilot subcarrier. Accordingly, it is possible to maximize a data rate by increasing the data signal for each single effective OFDM symbol.

The transmission efficiency ρ for each single effective OFDM symbol may be represented as,

$$ρ = \frac{{N}_{data}}{{N}_{used}} = \frac{{N}_{used} - {N}_{pilot}}{{N}_{used}} = 1 - \frac{{N}_{pilot}}{{N}_{used}} < 1 , \qquad [ Equation 2 ]$$

where ρ denotes the transmission efficiency, N_{used} denotes a number of used subcarriers, N_{data} denotes a number of data subcarriers, and Nₚᵢₗₒₜ denotes a number of pilot subcarriers.

It can be known that the transmission efficiency increases as the number of pilot subcarriers decreases. According to an aspect of the present invention, the transmitter and the receiver may increase the transmission efficiency for each effective OFDM symbol to ‘1’ by using a signal in which the pilot signal is added to the data signal. This may mean that as all the used subcarriers can be used as the data subcarriers, it is possible to maximize the transmission efficiency.

The pilot signal may use a signal that can prevent a peak-to-average power ratio (PAPR) of a transmission signal from significantly increasing and also can improve channel estimation performance. For example, a signal of Constant Amplitude Zero Auto-Correlation (CAZAC) sequence may be used for the pilot signal.

Referring again to FIG. 3, the IFFT unit 120 may transform the data signal of the frequency domain with the added pilot signal to a time domain signal.

An output signal x[n] of the IFFT unit 120 may be represented as,

$$x [ n ] = IFFT [ X [ k ] ] = \frac{1}{N} {\sum }_{k = 0}^{N - 1} X [ k ] exp ( j 2 π nk \text{/} N ) , \qquad [ Equation 3 ]$$

where N denotes the number of subcarriers.

The IFFT unit 120 may perform IFFT per N units.

The guard interval inserting unit 130 may additionally insert a guard interval to the time domain signal output from the IFFT unit 120. The guard interval may be set to be greater than maximum local spreading of a channel. When transmitting an OFDM symbol according to an OFDM transmission scheme, the guard interval may be inserted between a previous OFDM symbol transmitted in a previous OFDM symbol time and a current OFDM symbol to be transmitted in a current OFDM symbol time in order to remove interference. The guard interval may use a cyclic prefix (CP) scheme of copying a predetermined number of final bits of the OFDM symbol of the time domain and inserting the bits in the effective OFDM symbol.

The D/A converter 140 may convert a digital signal output from the guard interval inserting unit 130 to an analog signal.

The RF processor 150 may include a filter, a pre-processor, and the like. The RF processor 150 may perform RF process for an output signal of the D/A converter 140 to be transmitted in the air and then may transmit the processed signal in the air via a transmitting antenna.

The transmission signal may be input into a receiver 200 via a predetermined multi-path channel.

The receiver 200 includes an RF processor 210, an analog-to-digital (A/D) converter 220, a guard interval removal unit 230, an FFT unit 240, a channel estimator 250, an equalizer 260, a pilot signal removal unit 270, an error signal detector 280, and a corrector 290.

The receiver 200 may receive a signal from the transmitter 100 via a receiving antenna. The received signal may be a different type of signal in which noise is added to the transmission signal via the multi-path channel. Accordingly, it may be required to compensate for a channel distortion.

The RF processor 210 may down-convert the received signal to an intermediate frequency (IF) band.

The A/D converter 220 may convert an analog signal output from the RF processor 210 to a digital signal.

The guard interval removal unit 230 may remove the guard interval in an output signal of the A/D converter 220.

The FFT unit 240 may transform an output signal of the guard interval removal unit 230 to a frequency domain signal.

The frequency domain signal Y[k] output from the FFT unit 240 may be represented as,

$$Y [ k ] = FFT [ y [ n ] ] = {\sum }_{k = 0}^{N - 1} y [ n ] exp ( - j 2 π nk \text{/} N ) = X [ k ] H [ k ] + W [ k ] , \qquad [ Equation 4 ]$$

where y[n]=h[n]*x[n]+w[n], h[n] denotes a channel impulse response of a transmission panel, and w[n] denotes additive white Gaussian noise included in a signal that is received via a transmission channel.

The channel estimator 250 may estimate a channel value from a time domain signal output from the guard interval removal unit 230.

The equalizer 260 may equalize the frequency domain signal output from the FFT unit 240 based on the estimated channel value. The equalizer 260 may function to compensate for the channel distortion of the received signal. An output signal of the equalizer 260 may be represented as,

\hat{X}ᵢ[k]=Y[k]/Ĥᵢ[k]. [Equation 5]

The pilot signal removal unit 270 may be an adder. The pilot signal removal unit 270 may remove the pilot signal in the output signal of the equalizer 260 and extract the data signal. An output signal of the pilot signal removal unit 270 may be represented as,

\hat{X}_{d,i}[k]=\hat{X}ᵢ[k]−xₚ[k], [Equation 6]

The data signal in which the pilot signal is removed may be output as a bit stream via a decoder (not shown).

The receiver 200 may perform iterative additional compensation in a decoding process in order to improve performance. The data signal in which the pilot signal is removed may be provided to the error signal detector 280 for the additional compensation.

The error signal detector 280 may receive the estimated channel value and the data signal in which the pilot signal is removed and output an error signal. The error signal detector 280 includes a hard-decision unit 281 to perform hard-decision for the signal in which the pilot signal is removed, a multiplier 282 to multiply the hard-decision signal by the estimated channel value, and an IFFT unit 283 to transform a frequency domain signal output from the multiplier 282 to a time domain signal. The error signal output from the error signal detector 280 may be represented as,

$${e}_{i} [ n ] = IFFT [ . {\hat{H}}_{i} [ k ] {\overline{X}}_{d , i} [ k ] ] = \frac{1}{N} {\sum }_{k = 0}^{N - 1} {\hat{H}}_{i} [ k ] {\overline{X}}_{d , i} [ k ] exp ( - j 2 π nk \text{/} N ) . \qquad [ Equation 7 ]$$

The corrector 290 may receive the output signal y[n] of the guard interval removal unit 230 and the error signal eᵢ[n] of the error signal detector 280 and then output a corrected signal y′ᵢ[n]. The corrector 290 may be an adder and the corrected signal may become an input signal of the channel estimator 250. Specifically, the channel estimator 250 may receive the corrected signal and thus more accurately estimate the channel value. Therefore, it is possible to improve the compensation performance with respect to the channel distortion. The corrected signal output from the corrector 290 may be represented as,

y′ᵢ[n]=y[n]−eᵢ[n], (e₀[n]=0), [Equation 8]

where i denotes a number of iterations in the correcting process and the error signal is set to zero in an initial state where i=0.

In the above-described transmitter and receiver, the adder 110 is provided before the IFFT unit 120. However, the present invention is not limited thereto. Specifically, the adder 110 may be provided after the IFFT unit 120. In this case, the adder 110 may function to overlap signals that are generated transforming the data signal and the pilot signal to time domain signals via the IFFT unit 120.

Hereinafter, a data transmitting and receiving method for improving a data rate according to an embodiment of the present invention will be described.

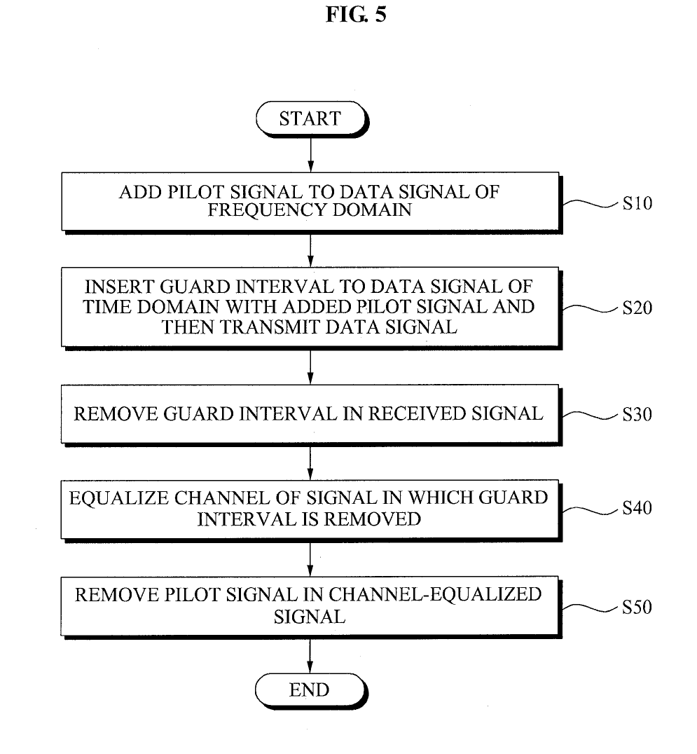

FIG. 5 is a flowchart illustrating a data transmitting and receiving method for improving a data rate according to an embodiment of the present invention. The method may be performed by components of the transmitter 100 and the receiver 200 shown in FIG. 3.

In operation S10, a pilot signal may be added to a data signal of a frequency domain.

The adder 110 of FIG. 3 may add the pilot signal to the data signal of the frequency domain.

The data signal may be a signal allocated to a used subcarrier by a subcarrier allocation unit (not shown). The pilot signal may be added to the data signal allocated to the subcarrier. However, the present invention is not limited thereto. Specifically, the pilot signal may be added after the data signal of the frequency domain is transformed to a data signal of a time domain.

The IFFT unit 120 may transform the data signal of the frequency domain with the added pilot signal to the data signal of the time domain. The IFFT unit 120 may perform IFFT per N units. N denotes a number of subcarriers.

In operation S20, a guard interval may be inserted to the data signal of the time domain with the added pilot signal.

Specifically, it is possible to perform RF processing for the data signal with the inserted guard interval and then transmit the data signal in the air via a transmitting antenna.

The receiver 100 may receive the signal from the transmitter 200 via a receiving antenna. The received signal may be down-converted to an intermediate frequency (IF) band.

In operation S30, the guard interval may be removed in the received signal.

Next, the signal in which the guard interval is removed may be converted to a frequency domain signal.

In operation S40, a channel of the signal in which the guard interval is removed may be equalized.

In this instance, the channel estimator 250 may estimate a channel value from the time domain signal in which the guard interval is removed. Next, the equalizer 260 may equalize the transformed frequency domain signal in which the guard interval is removed, based on the estimated channel value.

According to an aspect of the present invention, the estimating of the channel value and the converting of the time domain signal to the frequency domain signal may be simultaneously performed. However, the present invention is not limited thereto.

In operation S50, the pilot signal may be removed in the channel-equalized signal.

The pilot signal removal unit 270 may be an adder. The pilot signal removal unit 270 may remove the pilot signal in the channel-equalized signal to thereby output only the data signal.

The data signal may be provided to the error signal detector 280. The error signal detector 280 may perform hard-decision for the signal in which the pilot signal is removed, multiply the hard-decision signal by the estimated channel value, transform a frequency domain signal to a time domain signal, and then detect the error signal. The error signal and the time domain signal in which the guard interval is removed may be input in the corrector 290 to thereby output a corrected signal. The corrected signal denotes a signal in which the error is removed. The corrected signal may be input into the channel estimator 250. Accordingly, the channel estimator 250 may more accurately estimate the channel value.

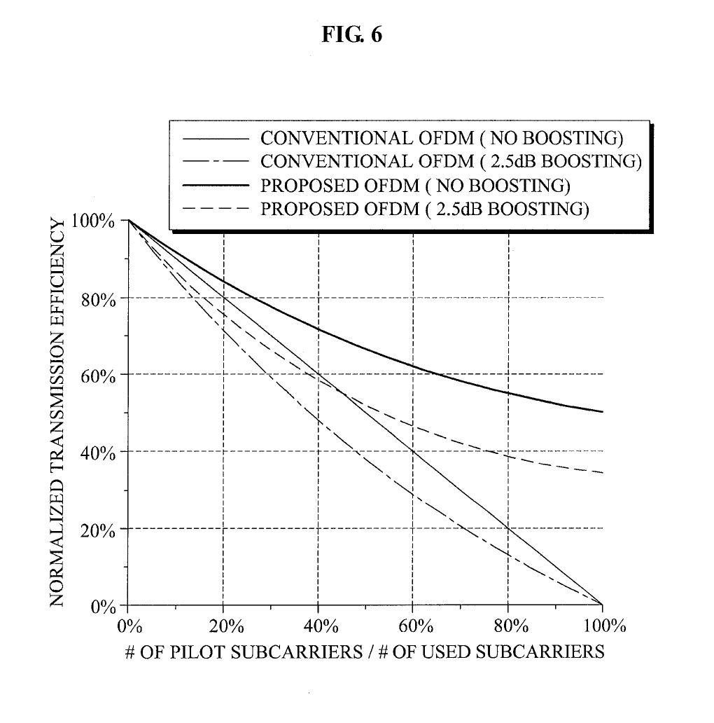

FIG. 6 illustrates a graph of comparing a data rate of the conventional data transmission method and a data rate of a data transmission method according to an embodiment of the present invention.

The conventional transmission method may add a pilot signal to a data signal to thereby transmit the data signal using a pilot subcarrier. The transmission scheme according to the present invention may add the pilot signal to the data signal allocated to a subcarrier to thereby transmit the data signal, instead of using the pilot subcarrier.

Referring to FIG. 6, the horizontal axis denotes the ratio of a number of pilot subcarriers to a number of used subcarriers and the vertical axis denotes a transmission efficiency. In this instance, two conditions were considered. One condition is when the power of the pilot signal and the power of the data signal are set to the same value (no boosting) and the other condition is when the power of the data signal is increased by 2.5 dB with respect to the power of the data signal (2.5 dB boosting). Consequently, in the case of both cases, it can be seen that the normalized transmission efficiency according to the present invention was improved in comparison to the conventional transmission method. Referring to the graph, in the conventional art, as the number of pilot subcarriers increased, the number of data subcarriers significantly decreased, reducing the transmission efficiency. However, according to the present invention, since the number of data subcarriers did not significantly decrease, the transmission efficiency was relatively improved.

The exemplary embodiments of the present invention include computer-readable media including program instructions to implement various operations embodied by a computer. The media may also include, alone or in combination with the program instructions, data files, data structures, tables, and the like. The media and program instructions may be those specially designed and constructed for the purposes of the present invention, or they may be of the kind well known and available to those having skill in the computer software arts. Examples of computer-readable media include magnetic media such as hard disks, floppy disks, and magnetic tape; optical media such as CD ROM disks; magneto-optical media such as floptical disks; and hardware devices that are specially configured to store and perform program instructions, such as read-only memory devices (ROM) and random access memory (RAM). Examples of program instructions include both machine code, such as produced by a compiler, and files containing higher level code that may be executed by the computer using an interpreter.

According to the present invention, there is provided a data transmitter and receiver for improving a data rate that can transmit and receive an OFDM symbol in which a pilot signal is added to a pilot signal and use all the used subcarriers as a subcarrier of the data signal, instead of using a pilot subcarrier of the pilot signal, and thereby can maximize a transmission efficiency for each single effective OFDM symbol. Also, it is possible to reduce interference with respect to an adjacent data signal by setting the power of the pilot signal to be less than the power of the data signal.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. A transmitter for transmitting an orthogonal frequency division multiplexing (OFDM) symbol in an OFDM system, the transmitter comprising:
a pilot adder to add a pilot signal to a data signal; and
a guard interval inserting unit to insert a guard interval to the data signal with the added pilot signal.

2. The transmitter of claim 1, further comprising:
an inverse fast Fourier transform (IFFT) unit to transform the data signal with the added pilot signal to a time domain signal.

3. The transmitter of claim 1, wherein the data signal is allocated to a subcarrier and the pilot adder adds the pilot signal to the data signal.

4. A receiver for receiving an OFDM symbol in which a pilot signal is added to a data signal in an OFDM system, the receiver comprising:
a guard interval removal unit to remove a guard interval in a received time domain signal;
a fast Fourier transform (FFT) unit to transform the time domain signal in which the guard interval is removed to a frequency domain signal;
a channel estimator to estimate a channel value from the time domain signal in which the guard interval is removed;
an equalizer to equalize the frequency domain signal based on the estimated channel value; and
a pilot signal removal unit to remove the pilot signal in the equalized frequency domain signal.

5. The receiver of claim 4, further comprising:
an error signal detector to receive the estimated channel value and the signal in which the pilot signal is removed, and output an error signal; and
a corrector to receive the error signal and the time domain signal in which the guard interval is removed, and output a corrected signal,
wherein the corrected signal is an input signal of the channel estimator.

6. The receiver of claim 5, wherein the error signal detector comprises:
a hard-decision unit to perform hard-decision for the signal in which the pilot signal is removed;
a multiplier to multiply the hard-decision signal by the estimated channel value; and
an IFFT unit to transform a frequency domain signal output from the multiplier to a time domain signal.

7. A method of transmitting an OFDM symbol in an OFDM system, the method comprising:
allocating a data signal to a subscriber;
adding a pilot signal to the allocated data signal; and
inserting a guard interval to the data signal with the added pilot signal to thereby transmit the data signal.

8. A method of receiving an OFDM symbol in which a pilot signal is added to a data signal in an OFDM system, the method comprising:
removing a guard interval in a received time domain signal;
estimating a channel value from the time domain signal in which the guard interval is removed;
compensating for the time domain signal in which the guard interval is removed with a channel distortion component based on the estimated channel value; and
removing the pilot signal in the compensated signal to thereby extract the data signal.

9. The method of claim 8, further comprising:
correcting the time domain signal in which the guard interval is removed prior to the estimating of the channel value.

10. The method of claim 9, wherein the correcting corrects the time domain signal by adding an error signal to the time domain signal in which the guard interval is removed, and the error signal is generated by performing hard-decision for the data signal in which the pilot signal is removed, multiplying the hard-decision signal by the estimated channel value, and transforming a frequency domain signal to a time domain signal.
